(19) United States
(12) Patent Application Publication
(10) Pub. No.: US 2013/0070798 A1
(43) Pub. Date: Mar. 21, 2013

(54) SEMICONDUCTOR LASER AND METHOD OF MANUFACTURING THE SAME

(71) Applicants: Go Sakaino, Tokyo (JP); Harunaka Yamaguchi, Tokyo (JP); Takashi Nagira, Tokyo (JP)

(72) Inventors: Go Sakaino, Tokyo (JP); Harunaka Yamaguchi, Tokyo (JP); Takashi Nagira, Tokyo (JP)

(73) Assignee: MITSUBISHI ELECTRIC CORPORATION, Tokyo (JP)

(21) Appl. No.: 13/587,036

(22) Filed: Aug. 16, 2012

(30) Foreign Application Priority Data
Sep. 16, 2011 (JP) 2011-202829
Mar. 22, 2012 (JP) 2012-065565

(51) Int. Cl. H01S 5/24; H01L 33/02

(52) U.S. Cl. 372/45.01; 438/39; 257/E33.023

(57) ABSTRACT

A semiconductor laser includes a semiconductor laser portion including an active layer portion having a p-type cladding layer, an active layer, and an n-type cladding layer on a p-type InP semiconductor substrate; and current confining structures that fill spaces on both sides of the semiconductor laser portion. Each of the current confining structures includes a first p-type InP layer, a Ru-doped InP layer, and a second p-type InP layer. The Ru-doped InP layer is in contact only with the first and second p-type InP layers. To obtain the structure, timing of introduction of a halogen-containing gas is adjusted.

### BACKGROUND OF THE INVENTION

1. Field of the Invention

The present invention relates to a semiconductor laser and a method of manufacturing the same, and more particularly, to a semiconductor laser and a method of manufacturing the same, which are capable of reducing an ineffective leakage current in a semiconductor laser portion to realize high-speed operation with low capacitance.

2. Description of the Related Art

In recent years, there is a marked increase in optical communication speed, which has expanded the applications that require high-speed operation of a semiconductor laser. To realize high-speed operation at low cost, a directly modulated semiconductor laser that directly modulates a distributed-feedback semiconductor laser at high speed has been demanded.

The high-speed directly modulated semiconductor laser needs to have a lower parasitic capacitance. Particularly in a buried structure having buried layers provided on both sides of an active layer, it is effective to use semi-insulating semiconductor layers as the buried layers. It is also necessary to suppress an ineffective leakage current that does not contribute to light emission. Accordingly, the semi-insulating semiconductor layer is typically structured with iron (Fe) as a dopant so as to trap electrons. Iron (Fe) has an effect of suppressing the leakage current. However, a p-type semiconductor layer typically uses zinc (Zn) as a dopant. Zinc (Zn) may cause severe interdiffusion with iron (Fe), thus leading to a problem in that the semi-insulating semiconductor layer cannot fully exert an intrinsic function of suppressing the leakage current. To address the problem, for example, as described in Japanese Patent Application Laid-open No. 2001-298240 (claim 4, and Example on pages 3-4) and Japanese Patent Application Laid-open No. 2011-134863 (paragraphs 0031-0034) (hereinafter, referred to as Patent Documents 1 and 2, respectively), it has been attempted to use, as a buried layer, a semi-insulating semiconductor layer using ruthenium (Ru) as a dopant, which hardly causes interdiffusion with zinc (Zn).

Patent Documents 1 and 2 describe that a Ru-doped semiconductor layer using ruthenium (Ru) as a dopant can obtain good semi-insulating properties. For example, as described in A. Dadgar et. al, “Ruthenium: A superior compensator of InP”, Applied Physics Letters, vol. 73, No. 26, pp. 3878-3880, the Ru-doped semiconductor layer has the property of trapping both electrons and holes. In the Ru-doped semiconductor layer, a current greatly varies when a voltage is applied, depending on the conductive type of semiconductor layers provided in contact at the top and bottom of the the Ru-doped semiconductor layer. The structure using p-type InP layers on both the upper and lower sides of the Ru-doped semiconductor layer can suppress an ineffective current most. In order to provide buried layers of a semiconductor laser with semi-insulating properties effective for reducing the leakage current, it is therefore necessary to surround the Ru-doped layer with p-type semiconductor layers.

Patent Document 1 discloses a technology of automatically allowing the periphery of the semi-insulating semiconductor layer to have the conductive type of p⁻ owing to diffusion of a p-type dopant. Actually, however, the conductive type of p⁻ cannot be obtained at side portions of an n-type semiconductor cladding layer, which constitute side surfaces of a striped mesa, with the result that parts of the side portions remain as semi-insulating layers. Therefore, there has been a problem in that a p-SI—n structure is locally formed and the buried layer has insufficient semi-insulating properties as a whole.

Patent Document 2 also employs the structure in which a Ru-doped semi-insulating block layer is partially in contact with an n-type semiconductor layer, and therefore has the same problem.

FIGS. 7 and 8 illustrate an example of a conventional semiconductor laser. Referring to FIGS. 7 and 8, the conventional semiconductor laser includes an n-type cladding InP layer 2, an active layer 3, a p-type cladding InP layer 4, Ru-doped InP layers 5, a p-type InP substrate 7, first p-type InP layers 9, an insulating film 10, and second p-type InP layers 11.

In the example illustrated in FIG. 7, the active layer 3 is formed into a mesa stripe, and the Ru-doped InP layers 5 are buried and grown on both sides of the active layer. If the Ru-doped InP layer 5 is grown in a growth layer under normal semiconductor growth conditions, as illustrated in FIG. 7, the Ru-doped InP layer 5 is abnormally grown to have an unevenness on the surface thereof. Therefore, various problems occur in the subsequent process of growth of a semiconductor layer and the wafer process. Therefore, as a solution for preventing the abnormal growth, the Ru-doped InP layer 5 is grown while a halogen-containing gas is introduced in a growth chamber. However, in the case of using the p-type InP substrate 7, if the gas is introduced at the start of the growth of the Ru-doped InP layer 5, the first p-type InP layer 9, which is grown on the side surface of the n-type cladding InP layer 2 which is the active layer, is etched. As a result, as illustrated in FIG. 8, the Ru-doped InP layer 5 is brought into contact with the n-type cladding InP layer 2. In this case, there has been a problem of the generation of a leakage current path.

Patent Document 2 discloses a technology of using a p-type AlInAs layer as a buried layer so as to increase a barrier for electrons and reduce a leakage current more. However, in the case of using the p-type AlInAs layer, if a halogen-containing gas is introduced at the start of growth of the Ru-doped InP layer, a part of AlInAs adhered in a growth apparatus is suspended in the growth apparatus. As a result, there has been a problem in that the surface of the Ru-doped InP layer becomes rough.

### SUMMARY OF THE INVENTION

The present invention has been made to solve the above-mentioned problems, and it is an object thereof to provide a semiconductor laser and a method of manufacturing a semiconductor laser, which are capable of suppressing an ineffective leakage current to realize high efficiency and high-speed operation.

According to the present invention, there is provided a method of manufacturing a semiconductor laser, including: layering, on a p-type semiconductor substrate, at least a p-type cladding layer, an active layer, and an n-type cladding layer in the stated order, thereby forming an active layer portion; etching the active layer portion to be processed into a mesa stripe, thereby forming a semiconductor laser portion; and layering, on the p-type semiconductor substrate on both sides of the semiconductor laser portion, a first p-type InP layer, a Ru-doped InP layer, and a second p-type InP layer in the stated order so as to fill a space on both the sides of the semiconductor laser portion, thereby forming current confining layers, in which the forming of the current confining layers includes: growing the first p-type InP layer on the p-type semiconductor substrate to form the first p-type InP layer; growing the Ru-doped InP layer on the first p-type InP layer to form the Ru-doped InP layer; and growing the second p-type InP layer on the Ru-doped InP layer to form the second p-type InP layer, and the forming of the Ru-doped InP layer includes, in order to obtain a structure in which the Ru-doped InP layer is in contact only with the first p-type InP layer and the second p-type InP layer, one of introducing a halogen-containing gas in a course of the growth of the Ru-doped InP layer, and introducing a halogen-containing gas at a start of the growth of the Ru-doped InP layer, changing a gas flow rate during the growth, and stopping the introduction of the halogen-containing gas after completion of the growth of the Ru-doped InP layer.

The present invention provides the method of manufacturing a semiconductor laser, including: the layering, on the p-type semiconductor substrate, at least the p-type cladding layer, the active layer, and the n-type cladding layer in the stated order, thereby forming the active layer portion; the etching the active layer portion to be processed into the mesa stripe, thereby forming the semiconductor laser portion; and the layering, on the p-type semiconductor substrate on both the sides of the semiconductor laser portion, the first p-type InP layer, the Ru-doped InP layer, and the second p-type InP layer in the stated order so as to fill the space on both the sides of the semiconductor laser portion, thereby forming the current confining layers, in which the forming of the current confining layers includes: the growing the first p-type InP layer on the p-type semiconductor substrate to form the first p-type InP layer; the growing the Ru-doped InP layer on the first p-type InP layer to form the Ru-doped InP layer; and the growing the second p-type InP layer on the Ru-doped InP layer to form the second p-type InP layer, and the forming of the Ru-doped InP layer includes, in order to obtain the structure in which the Ru-doped InP layer is in contact only with the first p-type InP layer and the second p-type InP layer, the one of the introducing the halogen-containing gas in the course of the growth of the Ru-doped InP layer, and the introducing the halogen-containing gas at the start of the growth of the Ru-doped InP layer, the changing the gas flow rate during the growth, and the stopping the introduction of the halogen-containing gas after the completion of the growth of the Ru-doped InP layer. Therefore, it is possible to suppress an ineffective leakage current to realize high efficiency and high-speed operation.

### BRIEF DESCRIPTION OF THE DRAWINGS

In the accompanying drawings:

FIG. 1 is an explanatory diagram illustrating the structure of a semiconductor laser according to a first embodiment of the present invention;

FIGS. 2A to 2I are a manufacturing flowchart illustrating the flow of processing of a method of manufacturing a semiconductor laser according to the first embodiment of the present invention;

FIG. 3 is an explanatory diagram illustrating the structure of a semiconductor laser according to a second embodiment of the present invention;

FIGS. 4A to 4C are explanatory diagrams illustrating modified examples of the first and second embodiments of the present invention;

FIGS. 5(a) and 5(b) are explanatory diagrams illustrating the method of manufacturing a semiconductor laser according to the first embodiment of the present invention;

FIGS. 6(a) and 6(b) are explanatory diagrams illustrating a method of manufacturing a semiconductor laser according to the second embodiment of the present invention;

FIG. 7 is an explanatory diagram illustrating the structure of a conventional semiconductor laser;

FIG. 8 is an explanatory diagram illustrating the structure of the conventional semiconductor laser; and

FIG. 9 is an explanatory diagram illustrating the relation between the Ru-InP thickness and the resistivity of a semiconductor laser according to a first embodiment of the present invention.

### DETAILED DESCRIPTION OF THE PREFERRED EMBODIMENTS

### First Embodiment

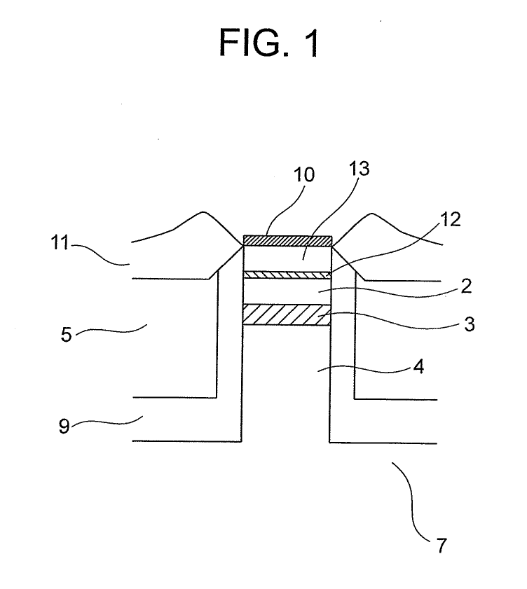

FIG. 1 illustrates the structure of a semiconductor laser manufactured by a manufacturing method according to a first embodiment of the present invention.

Referring to FIG. 1, in the semiconductor laser according to the first embodiment, a p-type InP cladding layer 4, an active layer 3, and an n-type InP cladding layer 2 are layered on a p-type InP semiconductor substrate 7 in the stated order, thereby forming a layered portion on the p-type InP semiconductor substrate 7. The layered portion is processed into a mesa stripe. On both sides of the mesa-striped layered portion, InP semiconductors are buried and grown to form current confining layers. The semiconductor laser according to the first embodiment is a distributed-feedback semiconductor laser structured in this way.

The current confining layers are each formed by layering a p-type InP layer 9, a Ru-doped InP layer 5, and a p-type InP layer 11 on the p-type InP semiconductor substrate 7 in the stated order. The Ru-doped InP layer 5 is in contact only with the p-type InP layers 9 and 11. The Ru-doped InP layer 5 is thus not in contact with the n-type InP cladding layer 2. No leakage current path is therefore generated, which can suppress a leakage current that does not pass through the active layer 3 and is ineffective for light emission. By adjusting the thickness of the Ru-doped InP layer 5, it is also possible to realize a lower capacitance which is necessary for high-speed modulation operation. In view of the high-speed modulation operation, it is desired to set the thickness of the Ru-doped InP layer 5 to approximately 1 to 5 μm.

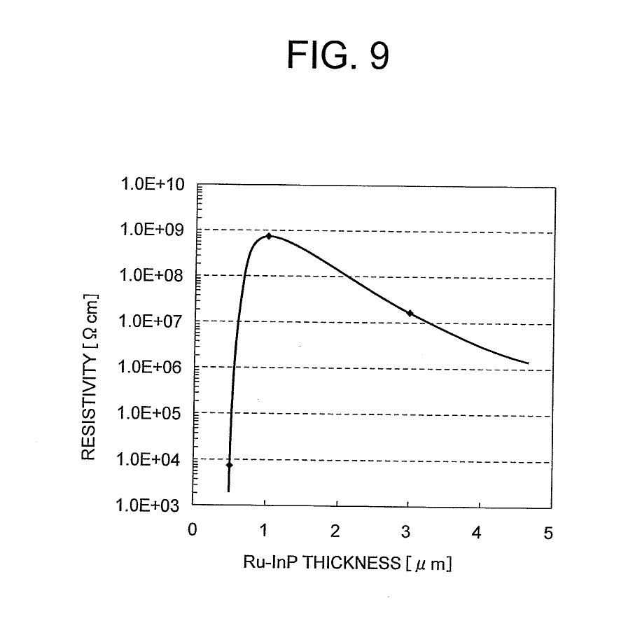

When the thickness of the Ru-doped InP layer 5 is too small, a sufficient resistivity necessary for semiconductor laser operation cannot be obtained. The reason is as follows. Zinc (Zn) is frequently used as p-type InP dopants, and zinc (Zn) diffuses very quickly in InP. A laser element, which needs buried growth, needs a plurality of crystal growth steps such as the growth of a contact layer after the buried growth. A high-temperature heat process is applied also to a buried growth portion every time the crystal growth step is performed. According to the experiment of the present invention, it has been revealed that, as shown in FIG. 9, the resistivity becomes significantly lower when the thickness of the Ru-doped InP layer 5 is less than 0.5 μm. The reason is that, after the buried growth portion is exposed to high temperature, the p-type dopants in the p-type InP layers 9 and 11 diffuse into the Ru-doped InP layer 5 and hence a net thickness of the Ru-doped InP layer 5 becomes smaller. In view of the diffusion, it is desired that the thickness of the Ru-doped InP layer 5 be 0.5 μm or more.

In conclusion, it is desirable that the thickness of the Ru-doped InP layer 5 should be 1 to 5 μm, and in this example, the thickness is set to 2 μm.

Referring to FIG. 1, a diffraction grating layer 12 is formed inside the n-type InP cladding layer 2, an n-type InP cladding layer 13 is laid on the diffraction grating layer 12, and an insulating film mask 10 for etching is provided on the n-type InP cladding layer 13.

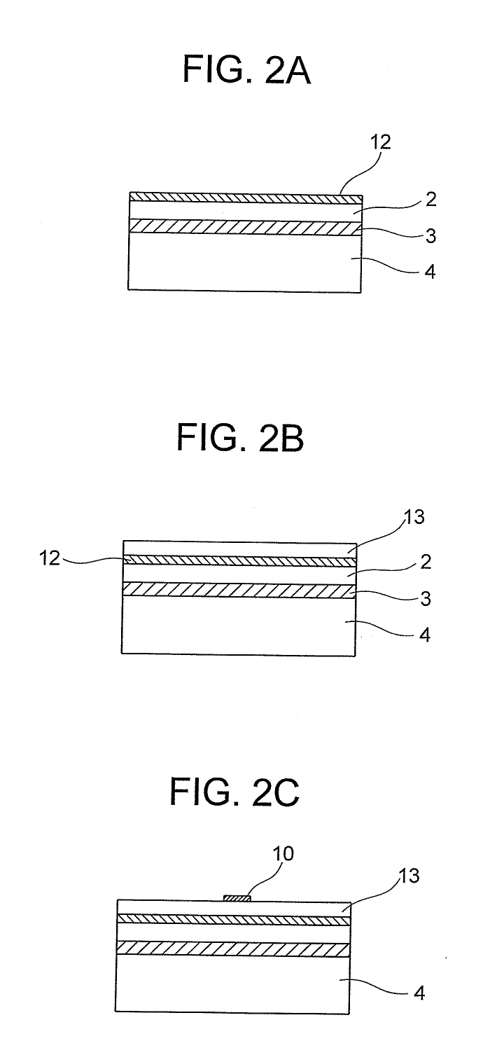

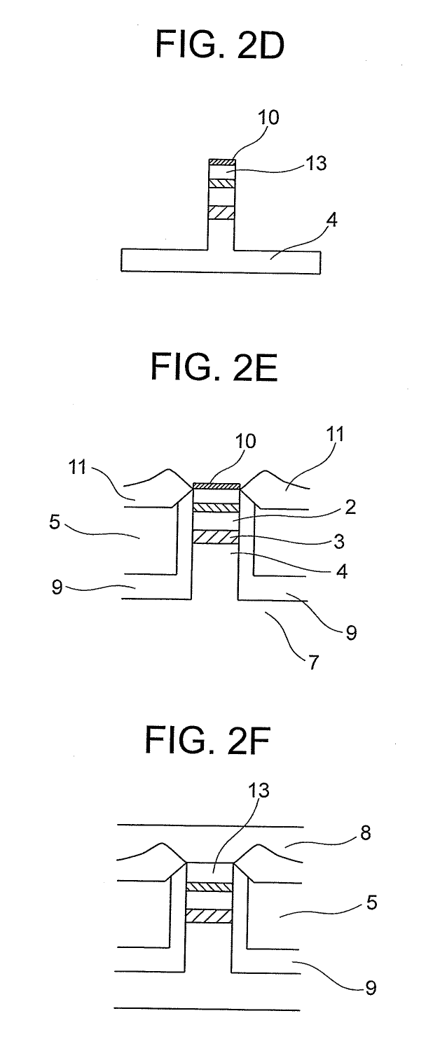

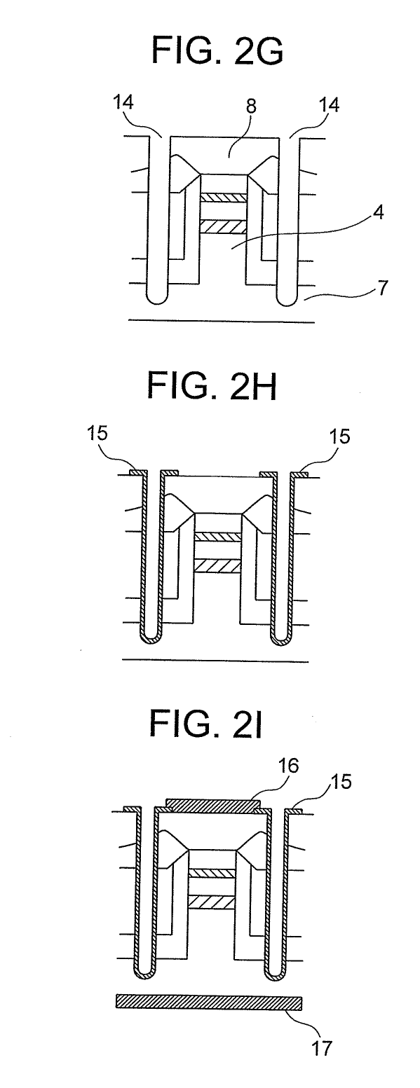

FIG. 1 illustrates the semiconductor laser in the course of the manufacturing process. A complete semiconductor laser has the structure illustrated in FIG. 2I, which is described below.

Hereinafter, referring to FIGS. 2A to 2I, a method of manufacturing a semiconductor laser according to the first embodiment is described.

First, as illustrated in FIG. 2A, on the (100)-plane oriented p-type semiconductor InP substrate 7 (not shown; see FIG. 2E), the p-type InP cladding layer 4, the active layer 3, and the n-type InP cladding layer 2 are layered in the stated order to form a layered portion. Next, interference exposure, electron beam exposure, or the like is used to form a grating on the n-type InP cladding layer 2, to thereby form the diffraction grating layer 12. The grating is formed so as to obtain an oscillation wavelength necessary for the diffraction grating layer 12 provided inside the n-type InP cladding layer 2.

Next, as illustrated in FIG. 2B, the n-type InP cladding layer 13 is further layered on the diffraction grating layer 12. Next, as illustrated in FIG. 2C, the n-type InP cladding layer 13 is partially covered with the insulating film mask 10 such as SiO₂, and the remaining part not covered with the insulating film mask 10 is etched to a depth of approximately 2 to 5 microns by dry etching or wet etching using a chemical solution. Then, as illustrated in FIG. 2D, the layered portion is processed into a mesa stripe. The mesa-striped layered portion is to serve as an active layer portion (semiconductor laser portion) of the semiconductor laser.

Next, as illustrated in FIG. 2E, on both sides of the active layer portion (semiconductor laser portion), the first p-type InP layer 9, the Ru-doped InP layer 5, and the second p-type InP layer 11, which are buried layers, are layered on the p-type semiconductor InP substrate 7 in the stated order. The thus formed layered portion including the first p-type InP layer 9, the Ru-doped InP layer 5, and the second p-type InP layer 11 is to serve as the current confining layer. To form the current confining layer, a halogen-containing gas is introduced to grow the Ru-doped InP layer 5 so that the Ru-doped InP layer 5 may be surrounded completely by the first p-type InP layer 9 and the second p-type InP layer 11 while not contacting the n-type InP cladding layer 2. The halogen-containing gas is introduced in a growth apparatus at timing in the course of the growth of the Ru-doped InP layer 5. Alternatively, the gas may be introduced at the start of the growth of the Ru-doped InP layer 5, the gas flow rate may be changed during the growth, and the introduction of the gas may be stopped at the completion of the growth of the Ru-doped InP layer 5.

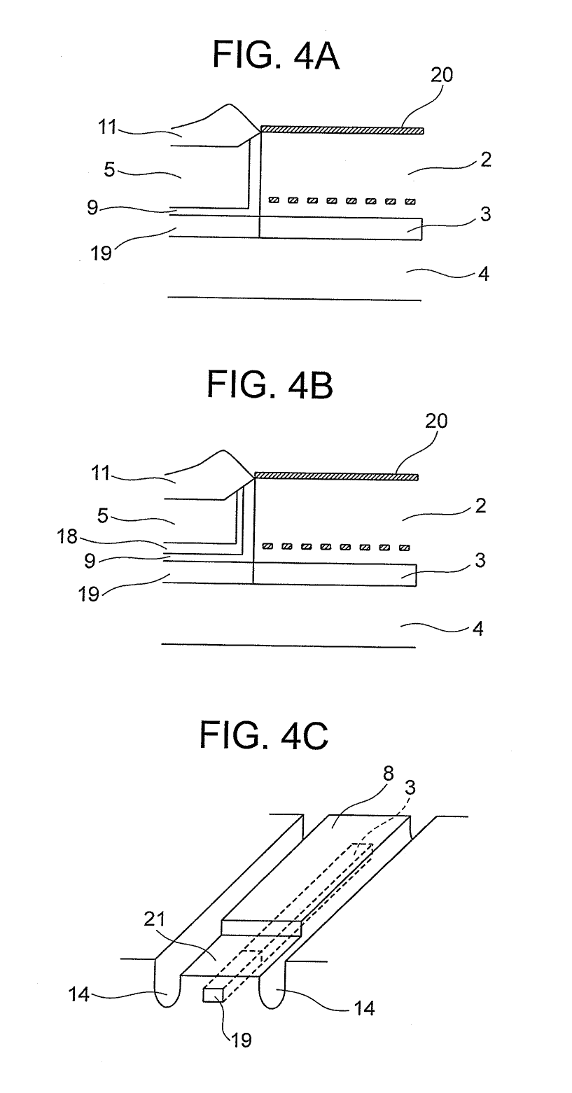

After that, as illustrated in FIG. 2F, the insulating film mask 10 is removed and an n-type InP contact layer 8 is then grown on the n-type InP cladding layer 13. The Ru-doped InP layer 5 is not in contact with the n-type InP contact layer 8, either, because the Ru-doped InP layer 5 is surrounded completely by the first p-type InP layer 9 and the second p-type InP layer 11. As illustrated in FIG. 2G, on both sides of the active layer portion (semiconductor laser portion), isolation grooves 14 are formed so as to pass through the n-type InP contact layer 8, the second p-type InP layer 11, the Ru-doped InP layer 5, and the first p-type InP layer 9 from the surface of the n-type InP contact layer 8 to reach the p-type InP cladding layer 4(or the p-type semiconductor InP substrate 7) (see FIG. 4C). Next, as illustrated in FIG. 2H, an insulating film 15 is formed on each inside wall of the isolation grooves 14.

As illustrated in FIG. 2I, an n-side electrode 16 is formed on the n-type InP contact layer 8 of the semiconductor laser portion through which a current is injected. The p-type semiconductor InP substrate 7 is subjected to grinding to a predetermined thickness, thereby forming a p-side electrode 17 on the lower surface of the p-type semiconductor InP substrate 7. After that, an optical end surface is formed using a crystal cleaved facet, and the end surface is subjected to coating for controlling the reflectance. Next, elements to be semiconductor lasers are separated from one another, thereby completing the semiconductor laser.

As described above, the semiconductor laser according to the first embodiment includes the semiconductor laser portion and the current confining layers provided on both sides thereof. The semiconductor laser portion is formed of the layered portion. The layered portion includes at least a p-type cladding layer (p-type InP cladding layer 4), the active layer 3, and an n-type cladding layer (n-type InP cladding layer 2), which are layered on a p-type semiconductor substrate (p-type semiconductor InP substrate 7) in the stated order. The semiconductor laser portion is processed into a mesa stripe, and a space on both sides of the semiconductor laser portion is filled with the current confining layers. The current confining layers each include a p-type InP layer (first p-type InP layer 9), the Ru-doped InP layer 5, and a p-type InP layer (second p-type InP layer 11), which are layered on the p-type semiconductor substrate (p-type semiconductor InP substrate 7) in the stated order, and the Ru-doped InP layer 5 is in contact only with the p-type InP layer (first and/or second p-type InP layer 9, 11). The current confining layer structured in this way fully exerts a current confinement effect. By adjusting the thickness of the Ru-doped InP layer 5, it is also possible to ensure a lower capacitance necessary for high-speed modulation operation.

According to a method of manufacturing the semiconductor laser having the above-mentioned structure, first, the p-type semiconductor substrate (p-type semiconductor InP substrate 7) is placed in a growth apparatus. On the p-type semiconductor substrate (p-type semiconductor InP substrate 7), the semiconductor laser portion formed of the layered portion including at least the p-type cladding layer (p-type InP cladding layer 4), the active layer 3, and the n-type cladding layer (n-type InP cladding layer 2) is formed. Next, the semiconductor laser portion is processed into a mesa stripe, and the current confining layers are buried on both sides thereof. The current confining layers are each formed by layering the p-type InP layer (first p-type InP layer 9), the Ru-doped InP layer 5, and the p-type InP layer (second p-type InP layer 11) in the stated order so that the Ru-doped InP layer 5 may be in contact only with the p-type InP layer (first and/or second p-type InP layer 9, 11). On this occasion, in order to realize the structure in which the Ru-doped InP layer 5 is in contact only with the p-type InP layer (first and/or second p-type InP layer 9, 11), the timing for introducing a halogen-containing gas in the growth apparatus is adjusted, and the gas is thus introduced at the adjusted appropriate timing. Specifically, when forming the current confining layer, the halogen-containing gas is introduced in the growth apparatus in the course of the growth of the Ru-doped InP layer 5. Alternatively, the p-type InP layers may be grown in a manner that the introduction of the gas is started at the start of the growth of the Ru-doped InP layer 5, the gas flow rate is increased during the growth, and the introduction of the gas is stopped at the completion of the growth of the Ru-doped InP layer 5. In this embodiment, where the semiconductor laser is manufactured in this way, the current confining layer has the structure in which the p-type InP layer (first p-type InP layer 9), the Ru-doped InP layer 5, and the p-type InP layer (second p-type InP layer 11) are layered in the stated order and the Ru-doped InP layer 5 is in contact only with the p-type InP layer (first and/or second p-type InP layer 9, 11), and hence the current confinement effect of the current confining layer is fully exerted. The thickness of the Ru-doped InP layer 5 can be freely adjusted as well, thus realizing a lower capacitance necessary for high-speed modulation operation.

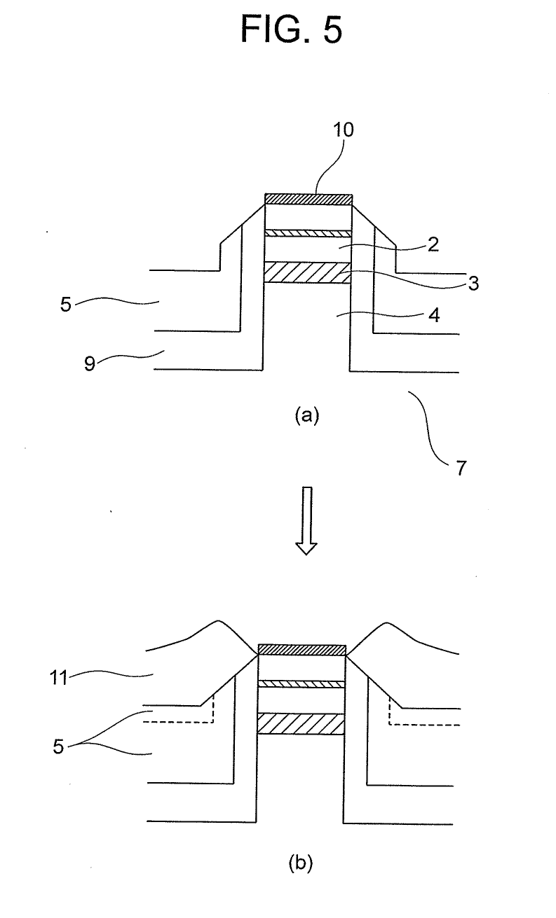

Referring to FIGS. 5(a) and 5(b), the introduction of a halogen-containing gas, which is the feature of this embodiment, is described in detail below.

After the growth of the first p-type InP layer 9 of the current confining layer, the growth of the Ru-doped InP layer 5 is started. The first p-type InP layer 9 is in contact with the p-type InP cladding layer 4, the active layer 3, and the n-type InP cladding layer 2. On this occasion, in the course of the growth of the Ru-doped InP layer 5 corresponding to the stage illustrated in FIG. 5(a), a halogen-containing gas such as a hydrogen chloride (HCl) gas is introduced in the growth apparatus in order to suppress abnormal growth of the Ru-doped InP layer 5. The introduction of the gas is stopped at the completion of the growth of the Ru-doped InP layer 5, and the second p-type InP layer 11 is grown, thereby completing the formation of the current confining layer (FIG. 5(b)). When the gas is introduced, the already-grown first p-type InP layer 9 starts to be etched. It is therefore necessary to appropriately adjust the gas introduction timing in order that the Ru-doped InP layer 5 may be surrounded completely by the p-type InP layer (first and/or second p-type InP layer 9, 11) so as not to contact the n-type InP layer 2. If the gas is introduced at an early timing, as illustrated in FIG. 8, the first p-type InP layer 9 is etched and the Ru-doped InP layer 5 is brought into contact with the n-type cladding InP layer 2, resulting in a structure with an increased leakage current. Actually, the gas is introduced at the stage at which the semiconductor layers (specifically, the first p-type InP layer 9 and the Ru-doped InP layer 5) have grown to such a thickness that would be etched by the introduced gas or more (FIG. 5(a)). The timing for introducing the gas depends on the growth rate of the current confining layer and the etching amount by the gas. For example, the gas is introduced at timing when a total thickness of the first p-type InP layer 9 and the Ru-doped InP layer 5 becomes approximately 0.5 μm or more. Note that, the above description assumes that no gas is introduced at all before the stage of FIG. 5(a). However, the same effects can be obtained also by a method in which the gas flow rate is reduced until the stage of FIG. 5(a) from the start of the growth of the Ru-doped InP layer 5 and then the gas flow rate is increased until the completion of the growth of the Ru-doped InP layer 5 from the stage of FIG. 5(a).

The technology of introducing a halogenated gas is disclosed also in Patent Document 2. In Patent Document 2, however, a semiconductor layer having a sufficient thickness is laid on the side surface of a mesa stripe before the growth of a semi-insulating semiconductor layer, and it is therefore unnecessary to start introducing the gas in the course of the growth of the semi-insulating semiconductor layer. Further, any gas introduction timing is not disclosed in Patent Document 2 because, by thickening the first n-type InP layer instead of thickening the mesa stripe side surface of the first p-type InP layer of FIG. 1 in Patent Document 2, the semiconductor layer provided on the side surface of the mesa stripe right before the growth of the semi-insulating semiconductor layer can be adjusted to be thick without increasing the leakage current. Therefore, the present invention is different from Patent Document 2. Further, in the structure of the first embodiment, if the first p-type InP layer 9 is grown to be thick, such as about 0.5 μm or larger, before the growth of the Ru-doped InP layer 5, then a larger leakage current flows in the thick portion and good characteristics cannot be obtained. Thus, the above-mentioned manufacturing method according to the first embodiment is an effective solution.

Note that, the manufacturing method according to the first embodiment is also applicable to the case of forming an optical waveguide in a semiconductor laser including an optical waveguide layer 19 as illustrated in FIGS. 4A and 4C. Also in this case, the same effects can be obtained. The semiconductor laser illustrated in FIGS. 4A and 4C includes a semiconductor laser portion formed of the layered portion including at least the p-type InP cladding layer 4, the active layer 3, and the n-type InP cladding layer 2, which are layered on the p-type semiconductor InP substrate 7, and also includes the optical waveguide layer 19 involving cladding layers provided on a light output side of the semiconductor laser portion. As illustrated in FIG. 4C, the active layer 3 and the optical waveguide layer 19 are processed into a mesa stripe, both sides of which are filled with the semiconductor current confining layers. The other structures are the same as those of the semiconductor laser described with reference to FIGS. 1 and 2A to 2I.

An exemplary method of manufacturing a semiconductor laser including the optical waveguide layer 19 is described as follows. First, on the (100)-plane oriented p-type semiconductor InP substrate 7, the p-type InP cladding layer 4, the active layer 3, and the n-type InP cladding layer 2 are layered in the stated order. Next, interference exposure, electron beam exposure, or the like is used to form the diffraction grating layer 12 (not shown; see FIG. 2A) provided inside the n-type InP cladding layer 2. The n-type InP cladding layer 13 (not shown; see FIG. 2B) is further layered thereon. In order to remove a part of the layered structure in a light exit direction, the n-type InP cladding layer 13 is partially covered with an insulating film mask 20 such as SiO₂, and the remaining part not covered with the insulating film mask 20 is etched to a depth of the lower surface of the active layer 3 by dry etching or wet etching using a chemical solution. Then, the layered structure is grown as illustrated in FIG. 4A, and the manufacturing method of the first embodiment is applied for the growth of the Ru-doped InP layer 5 in the layered structure. After that, a part of the layered structure including the active layer 3 and the optical waveguide layer 19 is covered with the insulating film mask 10 such as SiO₂, and the remaining part not covered with the insulating film mask 10 is etched to a depth of approximately 2 to 5 microns by dry etching or wet etching using a chemical solution. In this way, the layered structure is shaped in a mesa stripe.

Also in the structure of FIGS. 4A and 4C, the current confining layers are formed on both sides of the mesa stripe, to thereby form a semiconductor laser. When forming the current confining layers, the manufacturing method of the first embodiment may be applied. That is, after the first p-type InP layer 9 is laid, the second p-type InP layer 11 is grown in a manner that a halogen-containing gas is introduced in a growth apparatus in the course of the growth of the Ru-doped InP layer 5, or alternatively, in a manner that the gas is introduced at the start of the growth of the Ru-doped InP layer 5, the gas flow rate is changed during the growth, and the introduction of the gas is stopped after the completion of the growth of the Ru-doped InP layer 5. After the insulating film mask 10 is removed, the n-type InP contact layer 8 is grown on the n-type InP cladding layer 13. At this time, the Ru-doped InP layer 5 is surrounded completely by the first p-type InP layer 9 and the second p-type InP layer 11, and is therefore not in contact with even the n-type InP contact layer 8. Note that, in the structure having the optical waveguide layer 19, in order to prevent a current from leaking from the active layer 3 to the optical waveguide layer 19, the n-type InP contact layer 8 provided above the optical waveguide layer 19 is partially etched and removed to form a contact layer removed portion 21.

As described above, in this embodiment, the semiconductor laser includes a distributed-feedback semiconductor laser portion formed of the layered portion in which at least the p-type cladding layer (p-type InP cladding layer 4), the active layer 3, and the n-type cladding layer (n-type InP cladding layer 2) are provided on the p-type semiconductor substrate (p-type semiconductor InP substrate 7). This semiconductor laser portion is processed into a mesa stripe, and the semiconductor current confining layers are buried on both sides of the mesa-striped semiconductor laser portion. The current confining layers each have a structure in which the p-type InP layer (first p-type InP layer 9), the Ru-doped InP layer 5, and the p-type InP layer (second p-type InP layer 11) are layered in the stated order and the Ru-doped InP layer 5 is in contact only with the p-type InP layer (first and/or second p-type InP layer 9, 11). Therefore, the current confining layers, which are buried layers, fully exert the current confinement effect. By adjusting the thickness of the Ru-doped InP layer 5, it is also possible to ensure a low capacitance necessary for high-speed modulation operation.

In this embodiment, in the manufacture of a semiconductor laser having the structure described above, when forming the current confining layer, in order to realize the structure in which the Ru-doped InP layer 5 is in contact only with the first and/or second p-type InP layer 9, 11, the p-type InP layer is grown in a manner that a halogen-containing gas is introduced in a growth apparatus in the course of growth of the Ru-doped InP layer 5, or alternatively, in a manner that the gas is introduced at the start of the growth of the Ru-doped InP layer 5, the gas flow rate is changed during the growth, and the introduction of the gas is stopped after the completion of the growth of the Ru-doped InP layer 5. Therefore, the current confining layer has the structure in which the first p-type InP layer 9, the Ru-doped InP layer 5, and the second p-type InP layer 11 are layered in the stated order and the Ru-doped InP layer 5 is in contact only with the first and/or second p-type InP layer 9, 11. The current confining layer fully exerts a current confinement effect. By adjusting the thickness of the Ru-doped InP layer 5, it is also possible to ensure a low capacitance necessary for high-speed modulation operation.

Further, the structure of the semiconductor laser and the manufacturing method therefor according to the first embodiment are also applicable to such a structure as illustrated in FIGS. 4A and 4C in which the optical waveguide layer 19 involving cladding layers is provided on a light output side of the semiconductor laser portion. Also in this case, the same effects can be obtained.

### Second Embodiment

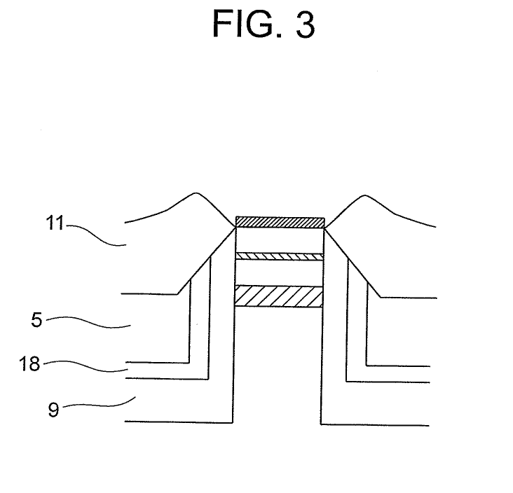

FIG. 3 illustrates the structure of a semiconductor laser manufactured by a manufacturing method according to a second embodiment of the present invention.

Referring to FIG. 3, the semiconductor laser according to the second embodiment is different from the semiconductor laser of the first embodiment only in that a p-type AlInAs layer 18 is interposed between the first p-type InP layer 9 and the Ru-doped InP layer 5 in the current confining layer of the first embodiment, and is otherwise the same as in the first embodiment.

The method of manufacturing a semiconductor laser according to the second embodiment is different from the manufacturing method of the first embodiment only in that the p-type AlInAs layer 18 is formed at the stage before the formation of the Ru-doped InP layer 5 after the formation of the first p-type InP layer 9. Otherwise, the same manufacturing method as in the first embodiment is applicable.

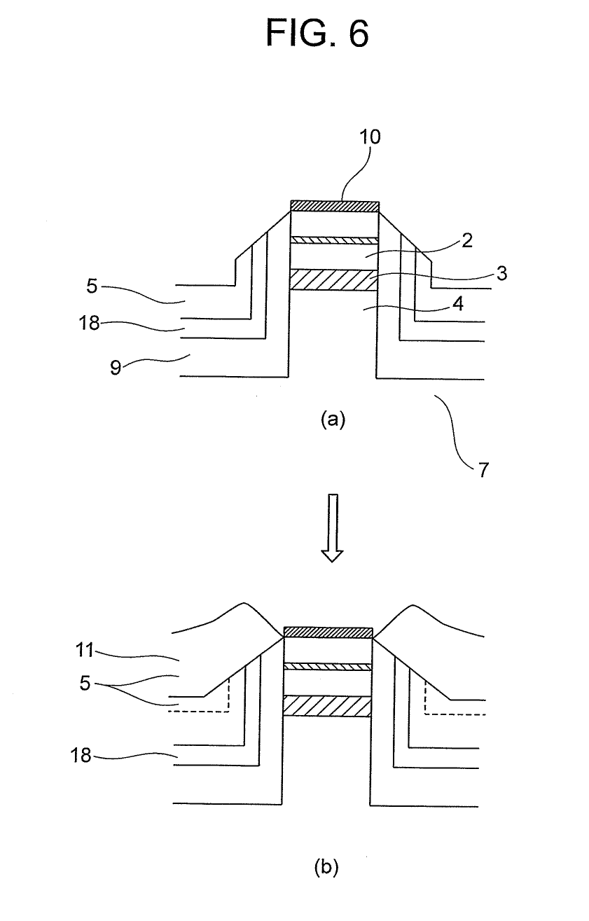

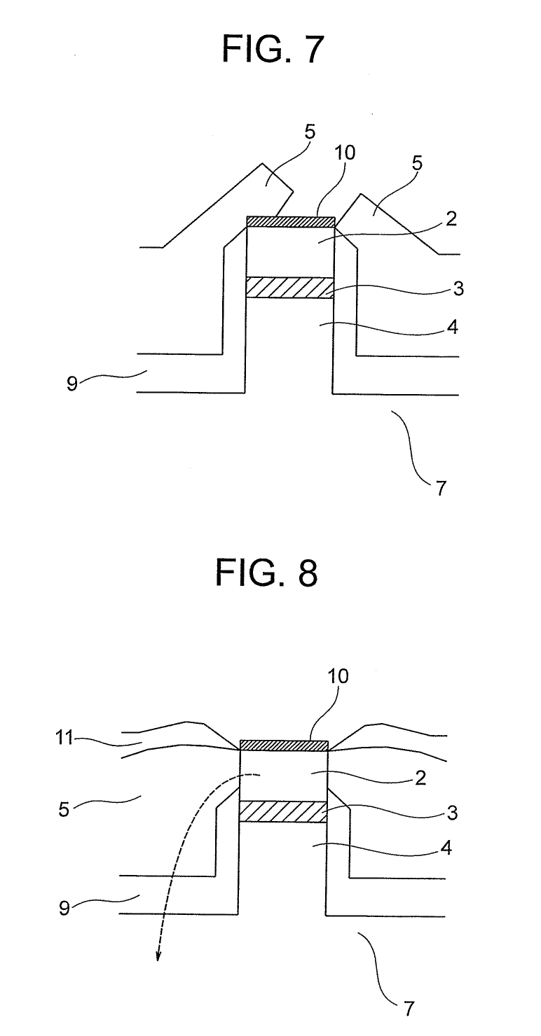

In the second embodiment, the introduction of a halogen-containing gas is started at the stage of FIG. 6(a) in the course of growth of the Ru-doped InP layer 5, and the introduction of the gas is stopped at the completion of the growth of the Ru-doped InP layer 5. After that, the second p-type InP layer 11 is grown, thereby completing the formation of a current confining layer (FIG. 6(b)). The p-type AlInAs layer 18 has a large energy barrier for electrons, and hence the use of the p-type AlInAs layer 18 can suppress overflow of electrons into the current confining layer from the active layer 3 so that a leakage current that does not pass through the active layer 3 and is ineffective for light emission can be reduced more than the first embodiment. In the manufacture of a semiconductor laser having the structure described above, if a halogen-containing gas is introduced at the start of the growth of the Ru-doped InP layer 5, in addition to the effect described in the first embodiment, an effect of preventing a problem such as surface roughness of a growth layer, which is otherwise caused when a part of the just-grown AlInAs layer adhered in the growth apparatus is suspended in the growth apparatus.

Note that, according to the structure using the p-type AlInAs layer 18 of the second embodiment, even if the first p-type InP layer 9 is not used, the same effects can be obtained in the manufacturing process. The AlInAs layer used for the current confining layer may be replaced with other materials, such as AlGaInAs, as long as the material has a stronger effect of suppressing overflow of electrons than InP has. Also in this case, the same effects can be obtained in the manufacturing process.

Note that, the method of manufacturing a semiconductor laser according to the second embodiment is also applicable to the case of forming an optical waveguide on an optical waveguide layer 19 in a semiconductor laser as illustrated in FIGS. 4B and 4C. This semiconductor layer includes a semiconductor laser portion provided on the p-type semiconductor substrate 7 and the optical waveguide layer 19 involving cladding layers provided on a light output side of the semiconductor laser portion. The semiconductor laser portion and the optical waveguide layer 19 are processed into a mesa stripe, and current confining layers are buried in a space on both sides of the mesa stripe. Also in this case, the same effects can be obtained.

In either structure of FIG. 3 or FIGS. 4B and 4C of the second embodiment, the same manufacturing method as in the above-mentioned first embodiment is applicable except for the use of the p-type AlInAs layer 18 in the layered structure. The gas introduction timing and the gas flow rate, which are the features of the present invention, are also the same as in the first embodiment.

As described above, in the second embodiment, the semiconductor laser includes a semiconductor laser portion formed of the layered portion in which at least the p-type cladding layer (p-type InP cladding layer 4), the active layer 3, and the n-type cladding layer (n-type InP cladding layer 2) are provided on the p-type semiconductor substrate (p-type semiconductor InP substrate 7). This semiconductor laser portion is processed into a mesa stripe, and the semiconductor current confining layers are buried on both sides of the mesa-striped semiconductor laser portion. The current confining layers each have a structure in which the p-type InP layer (first p-type InP layer 9), the p-type AlInAs layer 18, the Ru-doped InP layer 5, and the p-type InP layer (second p-type InP layer 11) are layered in the stated order and the Ru-doped InP layer 5 is in contact only with the p-type InP layer (p-type AlInAs layer 18 and/or second p-type InP layer 11). Therefore, the current confining layers, which are buried layers, fully exert the current confinement effect. By adjusting the thickness of the Ru-doped InP layer 5, it is also possible to ensure a low capacitance necessary for high-speed modulation operation.

According to a method of manufacturing the semiconductor laser having the above-mentioned structure, first, the p-type semiconductor substrate (p-type semiconductor InP substrate 7) is placed in a growth apparatus. On the p-type semiconductor substrate (p-type semiconductor InP substrate 7), the distributed-feedback semiconductor laser portion formed of the layered portion including at least the p-type cladding layer (p-type InP cladding layer 4), the active layer 3, and the n-type cladding layer (n-type InP cladding layer 2) is formed. Next, the semiconductor laser portion is processed into a mesa stripe, and the buried layers, which are to serve as the current confining layers, are formed on both sides thereof. The buried layers are each formed by layering the p-type InP layer (first p-type InP layer 9), the p-type AlInAs layer 18, the Ru-doped InP layer 5, and the p-type InP layer (second p-type InP layer 11) in the stated order so that the Ru-doped InP layer 5 may be in contact only with the p-type semiconductor layer (p-type AlInAs layer 18 and/or second p-type InP layer 11). On this occasion, in order to realize the structure in which the Ru-doped InP layer 5 is in contact only with the p-type semiconductor layer (p-type AlInAs layer 18 and/or second p-type InP layer 11), when forming the current confining layer, the p-type InP layer is grown in a manner that a halogen-containing gas is introduced in the growth apparatus in the course of the growth of the Ru-doped InP layer 5, or alternatively, in a manner that the gas is introduced at the start of the growth of the Ru-doped InP layer 5, the gas flow rate is changed during the growth, and the introduction of the gas is stopped after the completion of the growth of the Ru-doped InP layer 5. The semiconductor laser is manufactured in this way, and hence the current confining layer has the structure in which the p-type InP layer (first p-type InP layer 9), the p-type AlInAs layer 18, the Ru-doped InP layer 5, and the p-type InP layer (second p-type InP layer 11) are layered in the stated order and the Ru-doped InP layer 5 is in contact only with the p-type semiconductor layer (p-type AlInAs layer 18 and/or second p-type InP layer 11). The current confinement effect of the current confining layer is thus fully exerted. The thickness of the Ru-doped InP layer 5 can be adjusted as well, thus realizing a lower capacitance necessary for high-speed modulation operation.

The structure of the second embodiment, which uses the p-type AlInAs layer 18 having a large energy barrier for electrons, produces an effect of suppressing overflow of electrons into the current confining layer from the active layer 3 so that a leakage current that does not pass through the active layer 3 and is ineffective for light emission can be reduced more than the first embodiment.

The introduction of a halogen-containing gas at the start of growth of the Ru-doped InP layer 5 produces, in addition to the effect described in the first embodiment, an effect of preventing the problem of surface roughness of a growth layer, which is otherwise caused when a part of the just-grown AlInAs layer adhered in the growth apparatus is suspended in the growth apparatus.

1. A method of manufacturing a semiconductor laser, comprising:
layering, on a p-type semiconductor substrate, at least a p-type cladding layer, an active layer, and an n-type cladding layer, in that order, thereby forming an active layer portion;
etching the active layer portion to form a mesa stripe, thereby forming a semiconductor laser portion; and
layering, on the p-type semiconductor substrate, on both sides of the semiconductor laser portion, a first p-type InP layer, a Ru-doped InP layer, and a second p-type InP layer, in that order, filling space on both the sides of the semiconductor laser portion, thereby forming current confining structure, wherein
forming of the current confining structure comprises
growing the first p-type InP layer on the p-type semiconductor substrate,
growing the Ru-doped InP layer on the first p-type InP layer, and
growing the second p-type InP layer on the Ru-doped InP layer, and
growing the Ru-doped InP layer comprises one of (i) introducing a halogen-containing gas in a course of the growth of the Ru-doped InP layer, and (ii) introducing a halogen-containing gas at a start of the growth of the Ru-doped InP layer, changing gas flow rate during the growth of the Ru-doped InP layer, and stopping the introduction of the halogen-containing gas after completion of the growth of the Ru-doped InP layer, in order to obtain a structure in which the Ru-doped InP layer is in contact only with the first p-type InP layer and the second p-type InP layer.

2. The method of manufacturing a semiconductor laser according to claim 1, wherein forming of the current confining structure further comprises, between forming of the first p-type InP layer and forming of the Ru-doped InP layer, growing a p-type AlInAs layer on the first p-type InP layer to form the p-type AlInAs layer, so the p-type AlInAs layer is located between the first p-type InP layer and the Ru-doped InP layer.

3. A semiconductor laser, comprising:
a mesa-stripe semiconductor laser portion comprising an active layer portion, the active layer portion comprising a p-type cladding layer, an active layer, and an n-type cladding layer, which are layered on a p-type semiconductor substrate, in that order; and
current confining structures, each comprising a first p-type InP layer, a Ru-doped InP layer, and a second p-type InP layer, which are disposed on the p-type semiconductor substrate, in that order, the current confining structures filling space on both sides of the mesa-stripe semiconductor laser portion, wherein the Ru-doped InP layer is in contact only with the first p-type InP layer and the second p-type InP layer and is not in contact with the mesa-stripe semiconductor laser portion.

4. The semiconductor laser according to claim 3, wherein the Ru-doped InP layer has a thickness in a range from 1.0 μm to 5.0 μm.
